(19) United States
(12) Patent Application Publication
(10) Pub. No.: US 2025/0089382 A1
(43) Pub. Date: Mar. 13, 2025

(54) OPTICAL SEMICONDUCTOR DEVICE, OPTICAL RECEIVER, AND OPTICAL TRANSCEIVER

(71) Applicant: FUJITSU OPTICAL COMPONENTS LIMITED, Kawasaki-shi (JP)

(72) Inventor: Jianping WANG, Ota (JP)

(73) Assignee: FUJITSU OPTICAL COMPONENTS LIMITED, Kawasaki-shi (JP)

(21) Appl. No.: 18/785,642

(22) Filed: Jul. 26, 2024

(30) Foreign Application Priority Data
Sep. 13, 2023 (JP) 2023-148280

(51) Int. Cl. H01L 31/109; H01L 31/028; H01L 31/0352; H04B 10/61

(52) U.S. Cl. CPC H10F 30/222; H10F 77/122; H10F 77/147; H04B 10/613

(57) ABSTRACT

An optical semiconductor device includes: a first semiconductor layer having a first bandgap; and a second semiconductor layer having a second bandgap that is smaller than the first bandgap and formed on the first semiconductor layer. The first semiconductor layer includes a first conductive region with a first polarity, a second conductive region with a second polarity, and a first non-conductive region provided between the first conductive region and the second conductive region. The second semiconductor layer includes a third conductive region with the first polarity, and a second non-conductive region. The third conductive region is in contact with the first conductive region and the first non-conductive region. The second non-conductive region is in contact with at least one of the second conductive region and the first non-conductive region without being in contact with the first conductive region.

### CROSS-REFERENCE TO RELATED APPLICATION

This application is based upon and claims the benefit of priority of the prior Japanese Patent Application No. 2023-148280, filed on Sep. 13, 2023, the entire contents of which are incorporated herein by reference.

### FIELD

The embodiments discussed herein are related to an optical semiconductor device that converts an optical signal into an electrical signal, an optical receiver including the optical semiconductor device, and an optical transceiver including the optical semiconductor device.

### BACKGROUND

An optical receiver (alternatively, an optical transceiver including an optical receiver) is one of key devices for realizing high-speed optical communication. The optical receiver includes a photo detector that converts a received optical signal into an electrical signal. Therefore, in order to realize high-speed optical communication, a photo detector capable of high-speed operation is required.

The photo detector is realized by, for example, an optical semiconductor device such as a photodiode. In recent years, an optical semiconductor device manufactured by silicon photonics has attracted attention.

The photodiode includes an absorbing layer that absorbs light to generate pairs of electrons and holes. The electrons and/or holes generated in the absorbing layer are output via an electrode. As a result, an electrical signal representing an intensity of the input light is obtained. That is, the received optical signal is converted into an electrical signal.

A photodiode including a germanium layer as an absorbing layer has been proposed. For example, a photodetector described in Japanese Laid-open Patent Publication No. 2016-111363 includes an N-type silicon layer, a germanium layer, and a P-type silicon layer, and an optical signal is absorbed in the germanium layer. An electrical signal is generated from the absorbed optical signal. Then, the electrical signal is output to an outside of a photo detector via the N-type silicon layer and the P-type silicon layer.

In the photodiode including the germanium layer as the absorbing layer, electrons and holes generated in the germanium layer flow into the N-type silicon layer and the P-type silicon layer, respectively. At this time, hole accumulation occurs at a hetero interface between the germanium layer and the P-type silicon layer. Therefore, due to the spatial electric field effect, a moving speed of the holes is reduced, and a response speed to the change in the intensity of the input light is limited.

### SUMMARY

According to an aspect of the embodiments, an optical semiconductor device includes: a first semiconductor layer having a first bandgap; and a second semiconductor layer having a second bandgap that is smaller than the first bandgap and formed on the first semiconductor layer. The first semiconductor layer includes a first conductive region with a first polarity, a second conductive region with a second polarity, and a first non-conductive region provided between the first conductive region and the second conductive region. The second semiconductor layer includes a third conductive region with the first polarity, and a second non-conductive region. The third conductive region is in contact with the first conductive region and the first non-conductive region. The second non-conductive region is in contact with at least one of the second conductive region and the first non-conductive region without being in contact with the first conductive region.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of a structure of a photodiode;

FIG. 2 illustrates another example of the structure of the photodiode;

FIGS. 3A and 3B illustrate an example of an optical semiconductor device according to an embodiment of the present disclosure;

FIGS. 4A and 4B illustrate an operation of the optical semiconductor device illustrated in FIG. 2;

FIGS. 5A to 5C illustrate an operation of the optical semiconductor device according to the embodiment illustrated in FIGS. 3A and 3B;

FIG. 6 illustrates an example of a simulation result of an OE response with respect to a frequency;

FIGS. 7A and 7B illustrate examples of measurement results for the OE response with respect to the frequency;

FIG. 8 illustrates an example of an optical semiconductor device according to a first variation;

FIG. 9 illustrates an example of an optical semiconductor device according to a second variation;

FIG. 10 illustrates an example of an optical semiconductor device according to a third variation;

FIG. 11 illustrates an example of an optical semiconductor device according to a fourth variation;

FIG. 12 illustrates an example of an optical semiconductor device according to a fifth variation;

FIG. 13 illustrates an example of an optical semiconductor device according to a sixth variation; and

FIG. 14 illustrates an example of an optical transceiver on which an optical semiconductor device according to the embodiment is mounted.

### DESCRIPTION OF EMBODIMENTS

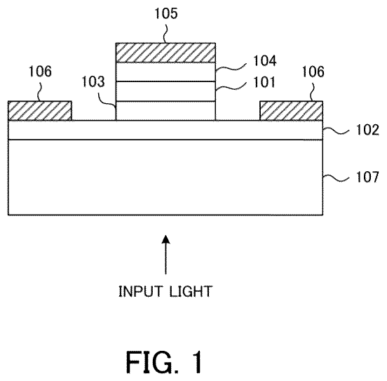

FIG. 1 illustrates an example of a structure of a photodiode. The photodiode includes a p-type light-absorbing layer 101, an n-type electrode layer 102, a carrier traveling layer 103, a p-type carrier blocking layer 104, an anode electrode 105, cathode electrodes 106, and a semi-insulating substrate 107.

Here, in general, in the semiconductor material, a drift speed of holes is lower than a drift speed of electrons. Therefore, a traveling time of a carrier is limited by the drift speed of the holes. Therefore, the photodiode illustrated in FIG. 1 adopts a uni-traveling carrier photodiode (UTC-PD) structure in order to shorten the carrier traveling time.

Light input from the semi-insulating substrate 107 side passes through the n-type electrode layer 102 and the carrier traveling layer 103, and is absorbed in the p-type light-absorbing layer 101. Then, pairs of electrons and holes are generated in the p-type light-absorbing layer 101. Among pairs of the electrons and holes generated in the p-type light-absorbing layer 101, the electrons diffuse to the carrier traveling layer 103 and reach the cathode electrodes 106 via the n-type electrode layer 102. As a result, an induced current is generated in an external circuit. Since the holes flow into the anode electrode 105, they hardly contribute to the induced current. As described above, the photodiode illustrated in FIG. 1 uses only electrons as carriers. Therefore, a response speed is improved.

However, in the structure illustrated in FIG. 1, a metal material (that is, anode electrode 105) is provided in the vicinity of the p-type light-absorbing layer 101. Therefore, a part of the input light is absorbed by the anode electrode 105. Here, when the input light is absorbed by the metal material, electrons and holes are not generated. That is, ineffective absorption occurs. Therefore, the conversion efficiency from the input light into the carrier is poor, and the light receiving sensitivity is low. In addition, the number of layers (n-type electrode layer 102, carrier traveling layer 103, p-type light-absorbing layer 101, and p-type carrier blocking layer 104) formed on a substrate is large, and a manufacturing process is complicated.

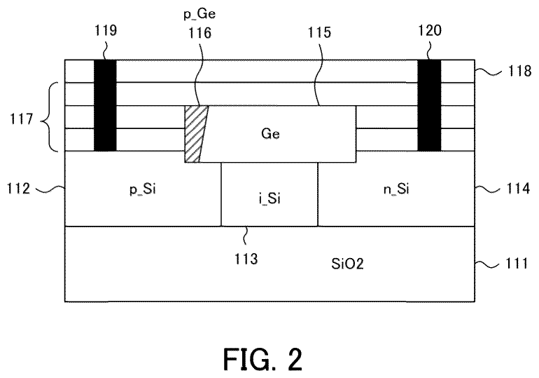

FIG. 2 illustrates another example of the structure of the photodiode. The photodiode includes an SiO2 layer 111, a p-type silicon layer 112, an intrinsic silicon layer 113, an n-type silicon layer 114, a germanium layer 115, waveguide layers 117, a passivation layer 118, and metal contact electrodes 119 and 120.

The germanium layer 115 is an intrinsic germanium region and is used as a light absorbing layer. In addition, the germanium layer 115 is in contact with the p-type silicon layer 112, the intrinsic silicon layer 113, and the n-type silicon layer 114. The germanium layer 115 may include a p-type germanium layer 116. In this case, the p-type germanium layer 116 is in contact with the p-type silicon layer 112. The metal contact electrode 119 is used as an anode electrode and is in contact with the p-type silicon layer 112. The metal contact electrode 120 is used as a cathode electrode and is in contact with the n-type silicon layer 114.

The input light is guided to the germanium layer 115 via the waveguide layers 117. In the germanium layer 115, electron-hole pairs are generated. Among the electron-hole pairs generated in the germanium layer 115, the electrons reach the metal contact electrode 120 via the n-type silicon layer 114. As a result, an induced current is generated in an external circuit. When the germanium layer 115 includes the p-type germanium layer 116, the electric field intensity in the germanium layer 115 increases, so that the drift speed of electrons increases. The holes flow into the p-type silicon layer 112.

However, in the structure illustrated in FIG. 2, the holes generated in the germanium layer 115 pass through a hetero interface between the germanium layer 115 and the p-type silicon layer 112. At this time, hole accumulation occurs at this interface, and the response speed decreases due to the spatial electric field effect. The term “intrinsic” means that an impurity concentration is sufficiently low and the semiconductor can be regarded as an intrinsic semiconductor.

### Embodiment

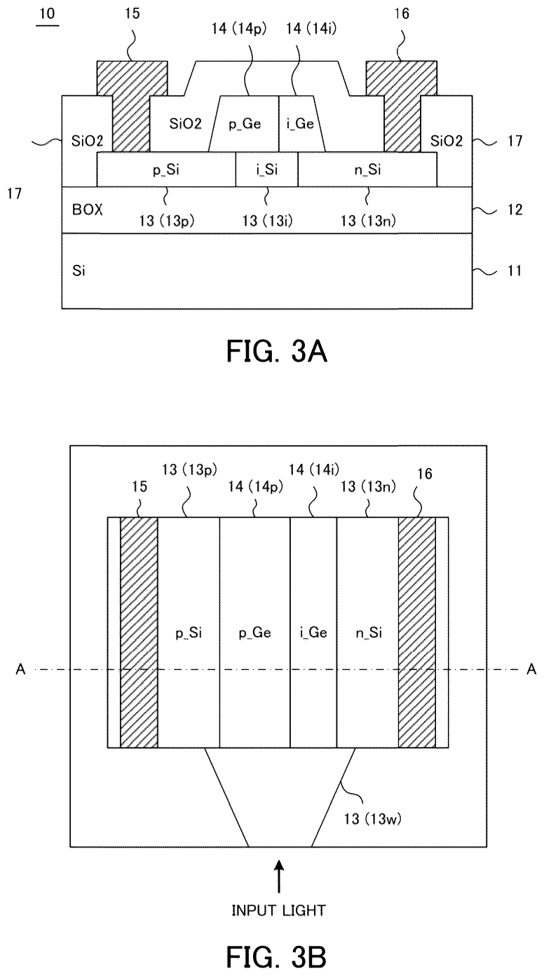

FIGS. 3A and 3B illustrate an example of an optical semiconductor device according to an embodiment of the present disclosure. An optical semiconductor device 10 according to the is a embodiment photo detector (alternatively, a photodiode) that converts input light into an electrical signal.

FIG. 3A is a cross-sectional view of the optical semiconductor device 10. FIG. 3B is a top view of the optical semiconductor device 10. Here, FIG. 3A illustrates an A-A cross section illustrated in FIG. 3B. Note that FIG. 3B illustrates an arrangement of the waveguides, and FIGS. 3A and 3B do not correspond exactly. For example, in FIG. 3B, the SiO2 layer 17 illustrated in FIG. 3A is omitted.

The optical semiconductor device 10 is formed on a surface of a silicon substrate 11. That is, the optical semiconductor device 10 is manufactured by silicon photonics.

A buried oxide (BOX) layer 12 is formed on an upper surface of the silicon substrate 11. The BOX layer 12 is an insulating film and is realized by, for example, SiO2.

A silicon (Si) layer 13 is formed on an upper surface of the BOX layer 12. A thickness of the silicon layer 13 is not particularly limited, but is, for example, about 0.2 μm. Further, the silicon layer 13 includes a p-type silicon region (p_Si) 13p, an n-type silicon region (n_Si) 13n, an intrinsic silicon region (i_Si) 13i as illustrated in FIG. 3A, and an optical waveguide 13w as illustrated in FIG. 3B. That is, the p-type silicon region 13p, the n-type silicon region 13n, the intrinsic silicon region 13i, and the optical waveguide 13w belong to the same semiconductor layer (that is, the silicon layer 13).

The p-type silicon region 13p is formed by selectively adding a p-type impurity to the silicon layer 13. As the p-type impurity, for example, boron, aluminum, gallium, indium, or the like may be added. The n-type silicon region 13n is formed by selectively adding an n-type impurity to the silicon layer 13. As the n-type impurity, for example, phosphorus, arsenic, antimony, or the like may be added.

Each of the p-type silicon region 13p and the n-type silicon region 13n contains impurities to such an extent as to be used as a conductive region. Although not particularly limited, an impurity concentration of the p-type silicon region 13p and the n-type silicon region 13n is 1×10¹7/cm³ or more.

As illustrated in FIG. 3A, the intrinsic silicon region 13i is formed between the p-type silicon region 13p and the n-type silicon region 13n. The intrinsic silicon region 13i is a silicon region having a sufficiently low impurity concentration. Here, “intrinsic” means a pure state containing no impurities. However, in this specification, a semiconductor having an impurity concentration low enough to be regarded as a non-conductive region may be referred to as an intrinsic semiconductor. In this example, the impurity concentration of the intrinsic silicon region 13i is 1×10¹⁶/cm³ or less. The intrinsic silicon region 13i is an example of a non-conductive region.

A germanium (Ge) layer 14 is formed on an upper surface of the silicon layer 13. Here, a bandgap of germanium is smaller than a bandgap of silicon. That is, a second semiconductor layer (here, the germanium layer 14) having a second bandgap smaller than a first bandgap is formed on an upper surface of the first semiconductor layer (here, the silicon layer 13) having the first bandgap. The bandgap of silicon is 1.11 eV, and the bandgap of germanium is 0.67 eV. The bandgap represents an energy difference between a top of a valence band and a bottom of a conduction band.

The germanium layer 14 includes a p-type germanium region (p_Ge) 14p. In this example, the germanium layer 14 includes the p-type germanium region 14p and an intrinsic germanium region (i_Ge) 14i. However, the germanium layer 14 may not include the intrinsic germanium region 14i. That is, the germanium layer 14 may include only the p-type germanium region 14p. The germanium layer 14 is used as a light absorbing layer of a photodiode.

The p-type germanium region 14p is formed by adding a p-type impurity to the germanium layer 14. As the p-type impurity, for example, boron, aluminum, gallium, indium, or the like may be added. The p-type germanium region 14p contains impurities to such an extent as to be used as a conductive region. Although not particularly limited, an impurity concentration of the p-type germanium region 14p is 1×10¹⁷/cm³ or more. The intrinsic germanium region 14i is a germanium region having a sufficiently low impurity concentration. In this example, the intrinsic germanium region 14i has an impurity concentration of 1×10¹⁶/cm³ or less. The intrinsic germanium region 14i is an example of a non-conductive region.

The p-type germanium region 14p is formed so as to be in contact with the p-type silicon region 13p and the intrinsic silicon region 13i. In addition, the p-type germanium region 14p is not in contact with the n-type silicon region 13n in the embodiment illustrated in FIG. 3A, but may be in contact with the n-type silicon region 13n.

In this example, the intrinsic germanium region 14i is formed so as to be in contact with the intrinsic silicon region 13i and the n-type silicon region 13n, as illustrated in FIG. 3A. However, the intrinsic germanium region 14i may be formed so as to be in contact with the n-type silicon region 13n without being in contact with the intrinsic silicon region 13i. In any case, the intrinsic germanium region 14i is formed on the upper surface of the silicon layer 13 so as not to be in contact with the p-type silicon region 13p. That is, the germanium layer 14 is formed such that the p-type silicon region 13p and the intrinsic germanium region 14i are not in contact with each other.

An electrode 15 is an anode electrode of a photodiode, and is in contact with the p-type silicon region 13p of the silicon layer 13. An electrode 16 is a cathode electrode of a photodiode, and is in contact with the n-type silicon region 13n of the silicon layer 13. Note that the SiO2 layer 17 is formed between the electrode 15 and the germanium layer 14. Furthermore, the SiO2 layer 17 is also formed between the electrode 16 and the germanium layer 14.

When the optical semiconductor device 10 having the above structure is used as a photo detector, a specified reverse bias voltage is applied. As an example, the electrode 15 used as an anode electrode is grounded to a ground potential, and a specified positive voltage (for example, 3 Volts) is applied to the electrode 16 used as a cathode electrode. In this case, a line of electric force directed from the electrode 16 to the electrode 15 is generated by the reverse bias voltage. A part of the line of electric force passes through the germanium layer 14.

The input light is guided to the optical semiconductor device 10 via the optical waveguide 13w illustrated in FIG. 3B. Here, the optical waveguide 13w is a part of the silicon layer 13 illustrated in FIG. 3A. Therefore, the input light is guided to the intrinsic silicon region 13i, the p-type silicon region 13p, and the n-type silicon region 13n. Further, the input light propagates from the silicon layer 13 to the germanium layer 14.

The input light is absorbed in the germanium layer 14. That is, the germanium layer 14 works as a light absorbing layer of a photodiode. In the germanium layer 14, electron-hole pairs of an amount corresponding to the intensity of the input light are generated.

Here, when the optical semiconductor device 10 is used as a photo detector, the specified reverse bias voltage is applied. Therefore, the electrons and holes generated in the germanium layer 14 move in a semiconductor region due to an electric field generated by the reverse bias voltage. Specifically, the electrons move from the germanium layer 14 to the electrode 16 through the intrinsic silicon region 13i and the n-type silicon region 13n. The holes diffuse from the germanium layer 14 into the p-type silicon region 13p. At this time, some holes may diffuse from the germanium layer 14 into the p-type silicon region 13p through the intrinsic silicon region 13i.

When the silicon layer 13 does not include the intrinsic silicon region 13i, the p-type silicon region 13p and the n-type silicon region 13n are in contact with each other. In this case, a depletion layer is generated at an interface of a pn junction. The depletion layer works as a capacitor and weakens the electric field due to the reverse bias voltage. That is, when the depletion layer is formed, the moving speed of the carrier (electron and/or hole) is reduced. Therefore, the optical semiconductor device 10 includes the intrinsic silicon region 13i between the p-type silicon region 13p and the n-type silicon region 13n. As a result, the influence of the depletion layer is alleviated. The intrinsic silicon region 13i works as a carrier traveling layer.

Thus, when light enters the optical semiconductor device 10, electron-hole pairs are generated in the germanium layer 14. The generated electrons and holes move to the electrode 16 and the electrode 15, respectively. Therefore, an induced current is generated in an external circuit coupled to the electrodes 15 and 16. That is, it is possible to detect a current or a voltage according to the intensity of the input light.

### EFFECTS

Next, effects of the structure according to the embodiment of the present disclosure will be described. Hereinafter, the structure illustrated in FIG. 2 is compared with the structure according to the embodiment illustrated in FIGS. 3A and 3B.

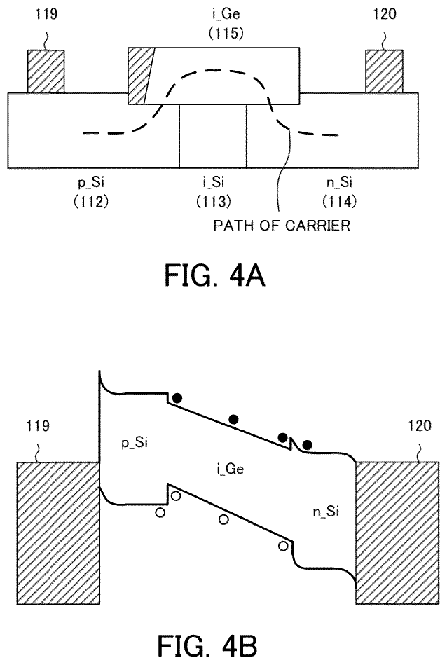

FIGS. 4A and 4B are views for describing an operation of the optical semiconductor device illustrated in FIG. 2. FIG. 4A illustrates a path through which carriers (electrons and holes) generated due to input light move. FIG. 4B illustrates an example of an energy band of the optical semiconductor device illustrated in FIG. 2. It is assumed that the specified reverse bias voltage is applied to the electrodes 119 and 120. In FIG. 4B, black circles and white circles represent electrons and holes, respectively.

When light enters the optical semiconductor device illustrated in FIG. 2, electron-hole pairs are generated in the germanium layer 115. Among the electron-hole pairs generated in the germanium layer 115, the electrons reach the metal contact electrode 120 via the n-type silicon layer 114. As a result, an induced current is generated in an external circuit coupled to the electrodes 119 and 120.

The holes diffuse from the germanium layer 115 to the p-type silicon layer 112. At this time, the holes generated in the germanium layer 115 pass through the hetero interface between the germanium layer 115 and the p-type silicon layer 112. However, a barrier that prevents diffusion of the holes exists at this interface. Therefore, hole accumulation occurs in the vicinity of the interface, and the response speed decreases due to the spatial electric field effect.

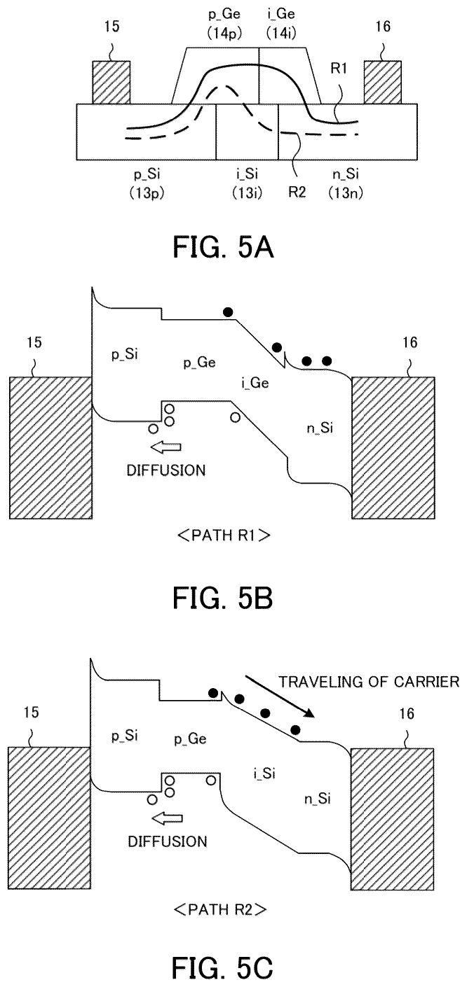

FIGS. 5A to 5C are views for describing the operation of the optical semiconductor device 10 according to the embodiment illustrated in FIGS. 3A and 3B. FIG. 5A illustrates a path through which carriers (electrons and holes) generated due to the input light move. FIGS. 5B and 5C illustrate an example of an energy band of the optical semiconductor device illustrated in FIGS. 3A and 3B. It is assumed that the specified reverse bias voltage is applied to the electrodes 15 and 16. In FIGS. 5B and 5C, black circles and white circles represent electrons and holes, respectively.

When light enters the optical semiconductor device illustrated in FIGS. 3A and 3B, electron-hole pairs are generated in the germanium layer 14. Here, the electrons generated in the germanium layer 14 can move to the electrode 16 via two paths illustrated in FIG. 5A. Specifically, the electrons can move through a path R1 from the germanium layer 14 to the n-type silicon region 13n without passing through the intrinsic silicon region 13i, and a path R2 from the germanium layer 14 to the n-type silicon region 13n via the intrinsic silicon region 13i.

The holes generated in the germanium layer 14 diffuse into the p-type silicon region 13p. At this time, the holes generated in the germanium layer 14 pass through a hetero interface between the germanium layer 14 and the p-type silicon region 13p. A barrier that prevents diffusion of the holes exists at this interface. However, in the optical semiconductor device 10 illustrated in FIGS. 3A and 3B or FIGS. 5A to 5C, the germanium layer 14 in contact with the hetero interface is the p-type germanium region 14p. A large number of holes exist in the p-type germanium region 14p. Therefore, the holes generated in the germanium layer 14 easily exceed the barrier in a diffusion process from the germanium layer 14 to the p-type silicon region 13p. That is, hole accumulation hardly occurs at the hetero interface between the germanium layer 14 and the p-type silicon region 13p. As a result, as compared with the structure illustrated in FIG. 2, in the optical semiconductor device 10 according to the embodiment illustrated in FIGS. 3A and 3B, a diffusion speed (alternatively, the moving speed of the holes) of the holes is increased, and the high-speed response of the photodiode is realized. In particular, since the hole accumulation at the hetero interface between the germanium layer 14 and the p-type silicon region 13p becomes significant at the time of high-power light input, it is expected that the speed of the optical semiconductor device 10 according to the embodiment illustrated in FIGS. 3A and 3B becomes significantly faster as compared with the structure illustrated in FIG. 2.

In addition, the carriers moving in the carrier traveling layer (that is, the intrinsic silicon region 13i) in the path R2 are electrons. Thus, as illustrated by the energy band in FIG. 5C, the structure of the optical semiconductor device 10 according to the embodiment may be regarded as a structure equivalent to the uni-traveling carrier photodiode (UTC-PD). Here, since the traveling speed of the electrons is faster than the traveling speed of the holes, a higher speed is expected by the structure illustrated in FIGS. 3A and 3B.

Note that the germanium layer 14 may not necessarily include the intrinsic germanium region 14i. That is, the germanium layer 14 may include only the p-type germanium region 14p. However, the configuration in which the germanium layer 14 includes the intrinsic germanium region 14i has the following advantages.
(1) By appropriately designing widths (or ratio) of the p-type germanium region 14p and the intrinsic germanium region 14i, a response speed determined by a sum of a drift process and a diffusion process can be maximized.
(2) The p-type germanium region 14p is formed, for example, by adding a p-type impurity to the germanium layer 14. At this time, when a shape or a position of a mask used to add the p-type impurity has an error, the p-type impurity may be added to the n-type silicon region 13n. In this case, the characteristics of the n-type silicon region 13n may deteriorate. Therefore, by providing the intrinsic germanium region 14i, the p-type impurity can be prevented from being added to the n-type silicon region 13n.

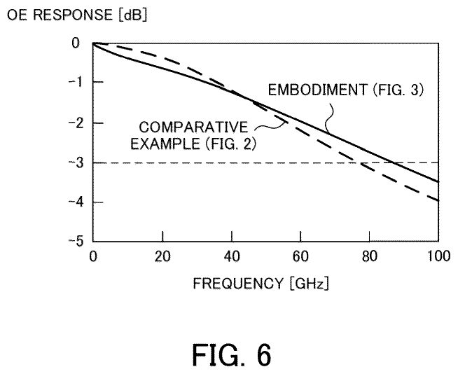

FIG. 6 illustrates an example of a simulation result of an OE (optical-to-electrical) response with respect to a frequency. Simulation conditions are as follows.
Wavelength of input light: 1.55 μm
Bias voltage: −3 Volts
Width of germanium layer (14): 2 μm
Thickness of germanium layer (14): 0.3 μm
Width of p-type germanium region (14p): 1 μm
Width of silicon layer (13): 21 μm
Thickness of silicon layer (13): 0.22 μm
Gap between p-type silicon region (13p) and n-type silicon region (13n): 0.4 μm

The simulation conditions are common to the structure illustrated in FIG. 2 and the structure according to the embodiment illustrated in FIGS. 3A and 3B. However, in the embodiment, the p-type germanium region 14p is in contact with the p-type silicon region 13p and the intrinsic silicon region 13i, and the intrinsic germanium region 14i is not in contact with the p-type silicon region 13p. On the other hand, in the structure illustrated in FIG. 2, a width of the p-type germanium region (116) is 0.2 μm, and the germanium layer 115, which is an intrinsic germanium region, is in contact with the p-type silicon region (112).

According to the above simulation, in any structure, the OE response characteristics deteriorate as the frequency increases. However, compared with the structure illustrated in FIG. 2, the OE response characteristics of the structure according to the embodiment illustrated in FIGS. 3A and 3B are improved. In this simulation, a −3 dB frequency of the OE response is improved by about 10 GHz. Note that “31 3 dB frequency” indicates a frequency at which OE response is decreased by 3 dB with respect to maximum OE response.

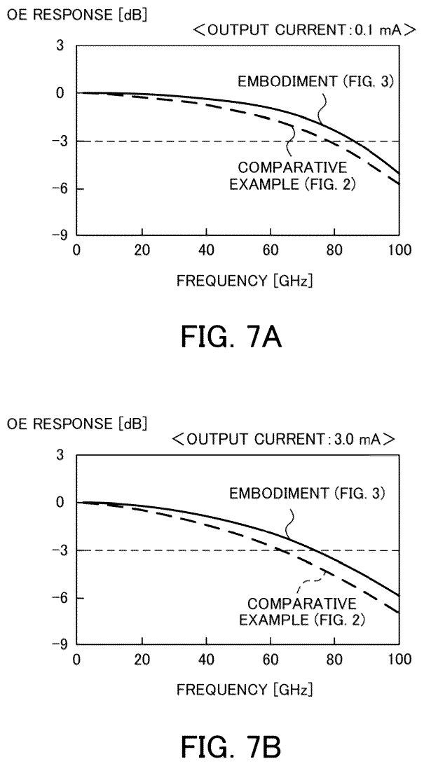

FIGS. 7A and 7B illustrate an example of measurement results for the OE response with respect to the frequency. FIG. 7A illustrates OE response characteristics with respect to the input light in which an output current of the photodiode is 0.1 mA. FIG. 7B illustrates OE response characteristics with respect to the input light in which an output current of the photodiode is 3 mA. Measurement conditions are as follows.
Temperature: 25° C.
Wavelength of input light: 1.55 μm
Bias voltage: −3 Volts
Width of germanium layer (14): 0.8 μm
Thickness of germanium layer (14): 0.15 μm
Width of silicon layer (13): 21 μm
Thickness of silicon layer (13): 0.22 μm
Gap between p-type silicon region (13p) and n-type silicon region (13n): 0.4 μm

The above measurement conditions are common in the structure illustrated in FIG. 2 and the structure according to the embodiment illustrated in FIGS. 3A and 3B. However, in the embodiment, the p-type germanium region 14p is in contact with the p-type silicon region 13p and the intrinsic silicon region 13i, and the intrinsic germanium region 14i is not in contact with the p-type silicon region 13p. On the other hand, in the structure illustrated in FIG. 2, the germanium layer 115, which is an intrinsic germanium region, is in contact with the p-type silicon region (112).

According to the above-described measurement results, by adopting the structure of the embodiment illustrated in FIGS. 3A and 3B, the frequency band is improved in comparison with the structure illustrated in FIG. 2. Specifically, as illustrated in FIG. 7A, the −3 dB frequency is improved by about 8.2 GHz when the power of the input light is low. As illustrated in FIG. 7B, the −3 dB frequency is improved by about 10.3 GHZ when the power of the input light is high. Note that, according to the structure of the embodiment, even when the output current of the photodiode is large (that is, when the power of the input light is high), since the −3 dB frequency exceeds 70 GHz, an optical signal of 130 Gbaud can be received using this optical semiconductor device.

As described above, according to the structure of the embodiment, it is possible to realize a higher response speed than the structure illustrated in FIG. 2. In addition, in the structure according to the embodiment, as illustrated electrode (that is, the in FIGS. 3A and 3B, a metal electrodes 15 and 16) is not provided in the vicinity of a region (that is, the germanium layer 14) that absorbs input light. Therefore, unlike the structure illustrated in FIG. 1, ineffective absorption by the metal electrode is reduced, so that conversion efficiency from an optical signal to an electrical signal is high.

Furthermore, in the structure according to the embodiment, the optical waveguide (in FIG. 3B, optical waveguide 13w) that propagates the input light is formed in the same process as the silicon layer 13. On the other hand, in the structure illustrated in FIG. 2, the waveguide layers 117 are formed in a process different from the silicon layer (112 to 114). Therefore, the manufacturing process of the optical semiconductor device 10 according to the embodiment is simpler than that of the structure illustrated in FIG. 2.

### VARIATIONS

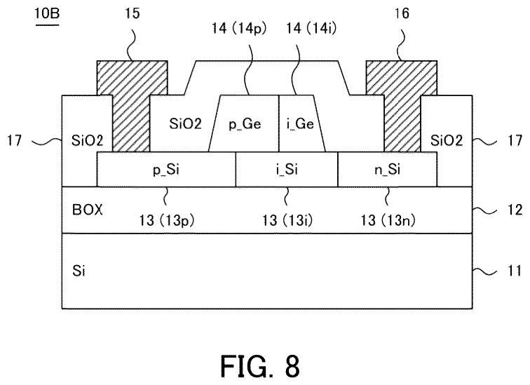

FIG. 8 illustrates an example of an optical semiconductor device according to a first variation. In an optical semiconductor device 10B according to the first variation, the p-type germanium region 14p is in contact with the p-type silicon region 13p and the intrinsic silicon region 13i. The intrinsic germanium region 14i is in contact with the intrinsic silicon region 13i. That is, unlike the structure illustrated in FIG. 3A, the intrinsic germanium region 14i is not in contact with the n-type silicon region 13n. In this case, the electrons generated in the germanium layer 14 move to the electrode 16 via the path R2 illustrated in FIG. 5A or 5C. That is, the electrons generated in the germanium layer 14 pass through the carrier traveling layer (intrinsic silicon region 13) and the n-type silicon region 13n to reach the electrode 16.

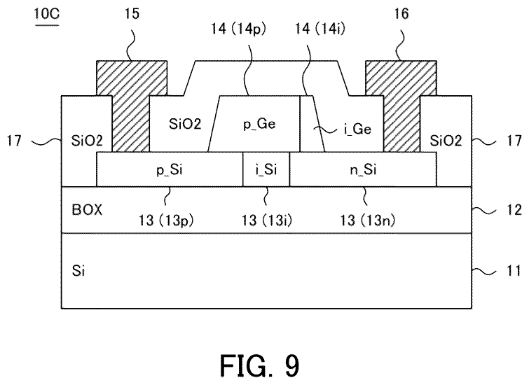

FIG. 9 illustrates an example of an optical semiconductor device according to a second variation. In an optical semiconductor device 10C according to the second variation, the p-type germanium region 14p is in contact with the p-type silicon region 13p, the intrinsic silicon region 13i, and the n-type silicon region 13n. In addition, the intrinsic germanium region 14i is in contact with the n-type silicon region 13n without being in contact with the p-type silicon region 13p and the intrinsic silicon region 13i.

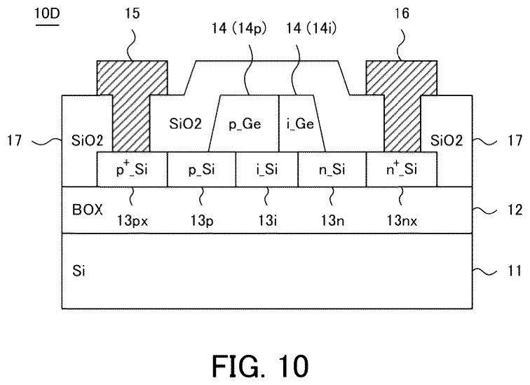

FIG. 10 illustrates an example of an optical semiconductor device according to a third variation. In an optical semiconductor device 10D according to the third variation, the silicon layer 13 includes a p⁺ type silicon region 13px, a p-type silicon region 13p, an intrinsic silicon region 13i, an n-type silicon region 13n, and an n⁺ type silicon region 13nx. The intrinsic silicon region 13i is provided between the p-type silicon region 13p and the n-type silicon region 13n. In addition, the p⁺ type silicon region 13px having an impurity concentration higher than that of the p-type silicon region 13p is provided in the p-type silicon region 13p or at an end portion of the p-type silicon region 13p, and the n⁺ type silicon region 13nx having an impurity concentration higher than that of the n-type silicon region 13n is provided in the n-type silicon region 13n or at an end portion of the n-type silicon region 13n. Note that the p⁺ type silicon region 13px is formed, for example, by further adding the p-type impurity to the p-type silicon region 13p. The n⁺ type silicon region 13nx is formed, for example, by further adding the n-type impurity to the n-type silicon region 13n.

The electrode 15 is in contact with the p⁺ type silicon region 13px. The electrode 16 is in contact with the n⁺ type silicon region 13nx. As described above, since the impurity concentrations of the semiconductor regions in contact with the electrodes 15 and 16 are high, the contact resistance is small, and the high-speed operation of the photodiode is realized.

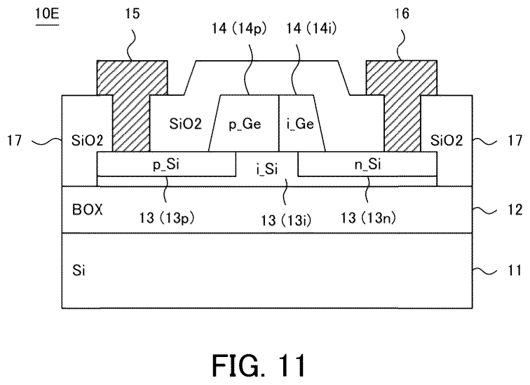

FIG. 11 illustrates an example of an optical semiconductor device according to a fourth variation. In an optical semiconductor device 10E according to the fourth variation, the p-type silicon region 13p and the n-type silicon region 13n are selectively formed in a region close to the upper surface of the silicon layer 13. That is, the region close to the bottom surface of the silicon layer 13 is formed of the same non-conductive material as the intrinsic silicon region 13i. In other words, the intrinsic silicon region 13i is formed between the p-type silicon region 13p and the n-type silicon region 13n in the region close to the upper surface of the silicon layer 13, and is formed over the entire region close to the bottom surface of the silicon layer 13. Here, the upper surface of the silicon layer 13 is a surface including a region in contact with the germanium layer 14 in the surface of the silicon layer 13, and the bottom surface of the silicon layer 13 is a surface facing the upper surface of the silicon layer 13 in the surface of the silicon layer 13.

The p-type silicon region 13p and the n-type silicon region 13n are each formed by adding and diffusing impurities so that the impurities do not reach the bottom surface of the silicon layer 13. According to this structure, ineffective absorption due to the impurity addition is suppressed. As a result, the efficiency of conversion from the input optical signal into the electrical signal is improved.

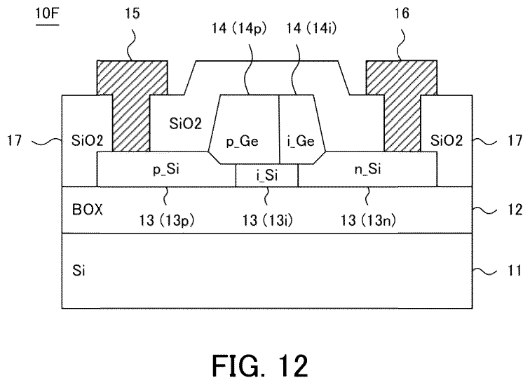

FIG. 12 illustrates an example of an optical semiconductor device according to a fifth variation. In an optical semiconductor device 10F according to the fifth variation, the silicon layer 13 includes a recess. That is, a “dent” is formed on an upper surface portion of the silicon layer 13. The recess is formed, for example, by selectively removing the upper surface portion of the silicon layer 13. At this time, the upper surface portion of the intrinsic silicon region 13i is removed. In addition, upper surface portions of the p-type silicon region 13p and the n-type silicon region 13n are removed respectively in the vicinity of the intrinsic silicon region 13i. The germanium layer 14 is formed on the recess. The p-type germanium region 14p is in contact with the p-type silicon region 13p and the intrinsic silicon region 13i, and the intrinsic germanium region 14i is in contact with the n-type silicon region 13n and the intrinsic silicon region 13i.

According to this structure, the input light is strongly confined in the waveguide, and the electron-hole pairs are efficiently generated. Therefore, the operation speed of the photodiode is improved.

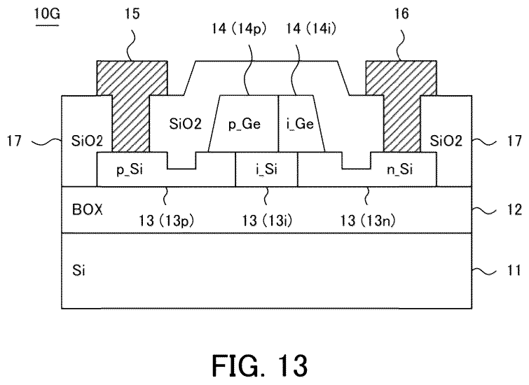

FIG. 13 illustrates an example of an optical semiconductor device according to a sixth variation. In an optical semiconductor device 10G according to the sixth variation, the silicon layer 13 includes a trench. The trench is formed in each of the p-type silicon region 13p and the n-type silicon region 13n on the upper surface of the silicon layer 13. In addition, the trench is formed at a position not in contact with the germanium layer 14. In this embodiment, the region where the trench is formed is filled with SiO2.

According to this structure, the input light is strongly confined in the waveguide, and the electron-hole pairs are efficiently generated. Therefore, the operation speed of the photodiode is improved.

### Optical Transceiver

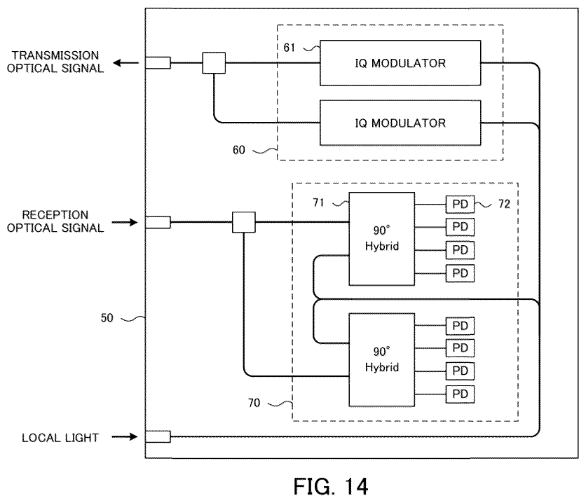

FIG. 14 illustrates an example of an optical transceiver on which the optical semiconductor device according to the embodiment is implemented. An optical transceiver 50 according to the embodiment includes an optical transmitter 60 and an optical receiver 70. The optical transceiver 50 is provided with local light generated by a light source (not illustrated). The local light is continuous wave light having a specified wavelength.

The optical transmitter 60 includes a set of IQ modulators 61. The IQ modulator 61 includes a set of Mach-Zehnder interferometers. A drive signal is applied to the IQ modulator 61 from a drive circuit (not illustrated). The drive signal represents transmission data. The IQ modulator 61 modulates the local light with the drive signal to generate a modulated optical signal. The modulated optical signals generated by the set of IQ modulators 61 are combined by a polarization beam combiner. As a result, a polarization multiplexed optical signal is generated.

The optical receiver 70 includes a 90-degree optical hybrid circuit 71 and a plurality of photo detectors 72. Here, it is assumed that the optical transceiver 50 receives a polarization multiplexed optical signal transmitted from another node. The polarization multiplexed optical signal is separated into an X-polarization component and a Y-polarization component whose polarizations are orthogonal to each other by a polarization beam splitter. The 90-degree optical hybrid circuit 71 extracts an in-phase (I) component signal and a quadrature (Q) component signal for each polarization component using the local light. As a result, four optical components (XI, XQ, YI, and YQ) are extracted from the received optical signal. Each optical component (XI, XQ, YI, and YQ) is converted into an electrical signal by the photo detector 72. That is, an electric field information signal representing the electric field of the received optical signal is generated.

The electric field information signal is guided to a data recovery circuit (not illustrated). The data recovery circuit recovers data by detecting a phase and an amplitude of the optical signal based on the electric field information signal. The data recovery circuit may include a phase estimator, a decision circuit, an error corrector, and the like.

In the optical receiver 70 having the above structure, each of the photo detectors 72 is realized by the optical semiconductor device 10 (or 10B to 10G) according to the embodiment. Here, the response speed of the optical semiconductor device 10 is improved. Therefore, the optical transceiver 50 or the optical receiver 70 can receive a broadband optical signal.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. An optical semiconductor device comprising:
a first semiconductor layer having a first bandgap; and
a second semiconductor layer having a second bandgap that is smaller than the first bandgap and formed on the first semiconductor layer, wherein
the first semiconductor layer includes
a first conductive region with a first polarity,
a second conductive region with a second polarity, and
a first non-conductive region provided between the first conductive region and the second conductive region,
the second semiconductor layer includes
a third conductive region with the first polarity, and
a second non-conductive region,
the third conductive region is in contact with the first conductive region and the first non-conductive region, and
the second non-conductive region is in contact with at least one of the second conductive region and the first non-conductive region without being in contact with the first conductive region.

2. The optical semiconductor device according to claim 1, wherein
the first semiconductor layer includes a waveguide that propagates input light to the optical semiconductor device.

3. The optical semiconductor device according to claim 1, further comprising:
a first electrode in contact with the first conductive region; and
a second electrode in contact with the second conductive region.

4. The optical semiconductor device according to claim 1, wherein
the third conductive region is in contact with the first conductive region, the first non-conductive region, and the second conductive region, and
the second non-conductive region is in contact with the second conductive region without being in contact with the first conductive region and the first non-conductive region.

5. The optical semiconductor device according to claim 1, wherein
a first high-concentration region having the first polarity and having an impurity concentration higher than that of the first conductive region is formed in the first conductive region without being in contact with the first non-conductive region,
a second high-concentration region having the second polarity and having an impurity concentration higher than that of the second conductive region is formed in the second conductive region without being in contact with the first non-conductive region, and
electrodes are in contact with the first high-concentration region and the second high-concentration region, respectively.

6. The optical semiconductor device according to claim 1, wherein
the first conductive region and the second conductive region are formed on an upper surface portion of the first semiconductor layer, and
a bottom surface of the first semiconductor layer is formed of a non-conductive material.

7. The optical semiconductor device according to claim 1, wherein
a recess is provided on an upper surface of the first semiconductor layer, and
the second semiconductor layer is formed in the recess.

8. The optical semiconductor device according to claim 1, wherein
a trench is provided at a position not in contact with the second semiconductor layer on an upper surface of the first semiconductor layer.

9. The optical semiconductor device according to claim 1, wherein
impurity concentrations of the first conductive region, the second conductive region, and the third conductive region are each 1×10¹⁷/cm³ or more, and
impurity concentrations of the first non-conductive region and the second non-conductive region are each 1×10¹⁶/cm³ or less.

10. The optical semiconductor device according to claim 1, wherein
the first semiconductor layer is formed of silicon,
the second semiconductor layer is formed of germanium,
the first polarity is p-type, and
the second polarity is n-type.

11. An optical receiver comprising:
an optical circuit that extracts an I (in-phase) component signal and a Q (quadrature) component signal from a received optical signal; and
a plurality of optical semiconductor devices that convert the I component signal and the Q component signal into electrical signals, respectively, wherein
each optical semiconductor device includes
a first semiconductor layer having a first bandgap, and
a second semiconductor layer having a second bandgap that is smaller than the first bandgap and formed on the first semiconductor layer,
the first semiconductor layer includes
a first conductive region with a first polarity,
a second conductive region with a second polarity, and
a first non-conductive region provided between the first conductive region and the second conductive region,
the second semiconductor layer includes
a third conductive region with the first polarity, and
a second non-conductive region,
the third conductive region is in contact with the first conductive region and the first non-conductive region,
the second non-conductive region is in contact with at least one of the second conductive region and the first non-conductive region without being in contact with the first conductive region,
the I component signal. is input to the second semiconductor layer of a first optical semiconductor device among the plurality of optical semiconductor devices, and
the Q component signal 1 is input to the second semiconductor layer of a second optical semiconductor device among the plurality of optical semiconductor devices.

12. An optical transceiver comprising an optical transmitter and an optical receiver, wherein
the optical receiver includes
an optical circuit that extracts an I (in-phase) component signal and a Q (quadrature) component signal from a received optical signal, and
a plurality of optical semiconductor devices that convert the I component signal and the @ component signal into electrical signals, respectively,
each optical semiconductor device includes
a first semiconductor layer having a first bandgap, and
a second semiconductor layer having a second bandgap that is smaller than the first bandgap and formed on the first semiconductor layer,
the first semiconductor layer includes
a first conductive region with a first polarity,
a second conductive region with a second polarity, and
a first non-conductive region provided between the first conductive region and the second conductive region,
the second semiconductor layer includes
a third conductive region with the first polarity, and
a second non-conductive region,
the third conductive region is in contact with the first conductive region and the first non-conductive region,
the second non-conductive region is in contact with at least one of the second conductive region and the first non-conductive region without being in contact with the first conductive region,
the I component signal is input to the second semiconductor layer of a first optical semiconductor device among the plurality of optical semiconductor devices, and
the Q component signal is input to the second semiconductor layer of a second optical semiconductor device among the plurality of optical semiconductor devices.
